(19) United States
(12) Patent Application Publication
(10) Pub. No.: US 2010/0289491 A1
(43) Pub. Date: Nov. 18, 2010

(54) RADIO FREQUENCY ATOMIC MAGNETOMETER

(76) Inventors: Dimitry Budker, El Cerrito, CA (US); Alexander Pines, Berkeley, CA (US); Michah Ledbetter, Oakland, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 12/679,000

(22) PCT Filed: Sep. 19, 2008
(86) PCT No.: PCT/US08/77113

§ 371 Date: Jul. 21, 2010

Related U.S. Application Data
(60) Provisional application No. 60/974,186, filed on Sep. 21, 2007.

(51) Int. Cl. G01R 33/44

(52) U.S. Cl. 324/304

(57) ABSTRACT

An atomic magnetometer is used to detect radio frequency magnetic fields, such as those generated in nuclear resonance experiments. The magnetometer is based on nonlinear magneto-optical rotation and pumps an atomic vapor into a quadrupole aligned state. Detection of the modulation of the polarization of a linearly polarized beam provides the radio frequency signal, which can then be processed to extract the component frequencies.

### RELATED APPLICATION

This application claims the benefit of U.S. Provisional Application No. 60/974,186, filed Sep. 21, 2007, which is incorporated herein by reference in its entirety.

### STATEMENT REGARDING FEDERALLY SPONSORED R&D

The U.S. Government has a paid-up license in this invention and the right in limited circumstances to require the patent owner to license others on reasonable terms as provided for by the terms of Contract No. DE-AC02-05CH11231 awarded by the Department of Energy.

### BACKGROUND

1. Field of the Invention

The present invention relates to magnetometers and nuclear resonance detectors.

2. Description of the Related Art

Many applications, such as nuclear magnetic resonance (including nuclear quadrupole resonance) and magnetic resonance imaging, require detection of radio frequency magnetic fields. Traditionally, such detection is conducted using inductive pick-up coils, or more recently, SQUID magnetometers. However, pickup coils are only efficient at high frequencies, necessitating high fields and correspondingly large, immobile magnets. Use of SQUID magnetometers permit lower leading field strengths; however, such magnetometers require cryogenic cooling and generate their own magnetic fields, which can have a back-reaction effect on a nuclear sample. Thus, there is a need for improved magnetometers capable of radio frequency detection.

### SUMMARY OF THE INVENTION

One embodiment disclosed herein includes a magnetometer that comprises a container comprising atomic vapor, a magnetic field generator configured to apply a substantially static magnetic field to the atomic vapor, and a linearly polarized light source configured to optically pump the atomic vapor into a substantially aligned state (one with a quadrupole moment).

Another embodiment disclosed herein includes a method of detecting time-varying magnetic fields including exposing an atomic vapor to a substantially static magnetic field, optically pumping the atomic vapor into a substantially aligned state, exposing the atomic vapor to a time-varying magnetic field, transmitting linearly polarized light through the atomic vapor, and detecting modulation of the polarization angle of the linearly polarized light.

Another embodiment disclosed herein includes a nuclear resonance detector that comprises a first magnetic field generator configured to apply a magnetic field to a sample, an inductor coil configured to apply a time-varying magnetic field to the sample at an angle relative to the magnetic field applied by the first magnetic field generator, a container comprising atomic vapor, and a linearly polarized light source configured to optically pump the atomic vapor into a substantially aligned state.

Another embodiment disclosed herein includes a method of nuclear resonance detection including generating a magnetic free precession signal from a sample, exposing an atomic vapor to the free precession signal, optically pumping the atomic vapor into a substantially aligned state, transmitting linearly polarized light through the atomic vapor, and detecting modulation of the polarization angle of the linearly polarized light.

Another embodiment disclosed herein includes a method of detecting fluid that includes exposing a flowing fluid to a magnetic field to enhance nuclear magnetization within the fluid and detecting the enhanced nuclear magnetization with a magnetometer downstream of where the fluid is exposed to the magnetic field.

### BRIEF DESCRIPTION OF THE DRAWINGS

FIG. 1 is a system block diagram illustrating a nuclear resonance apparatus using an atomic magnetometer for detection of radio frequency magnetic fields.

FIG. 2 is a diagram illustrating certain atomic states of ⁸⁷Rb undergoing optical excitation in the presence of a magnetic field.

FIG. 3 is a diagram illustrating an aligned quadrupole state of ⁸⁷Rb.

FIG. 4 is a system block diagram illustrating an atomic magnetometer.

FIG. 5 is a system block diagram illustrating an apparatus for generating a NMR free induction decay signal.

FIG. 6 is a system block diagram illustrating an experimental apparatus for testing a radio frequency atomic magnetometer.

FIG. 7 contains two panels with graphs of polarization rotation and transmission intensity of linearly polarized light as a function of optical detuning in a radio frequency atomic magnetometer.

FIG. 8 is a graph depicting optical rotation as a function of rf magnetic field frequency in a radio frequency atomic magnetometer.

FIG. 9 contains two panels with graphs depicting the half width at half maximum frequency width of optical rotation modulation and optical rotation amplitude as a function of light power in a radio frequency atomic magnetometer.

FIG. 10 is a graph depicting the noise floor of the magnetometer compared to a calibration peak

FIG. 11 is a graph depicting projected and experimentally measured magnetometer sensitivity as a function of light power.

FIG. 12 is a system block diagram illustrating an apparatus for detecting the magnetization of a flowing fluid.

FIG. 13 is a cross-section of fluid pipe having various constricted sections.

FIG. 14 is a graph depicting magnetizations of fluid flowing through various sections of constricted pipe.

FIG. 15A is a graph of the Fourier transformation of magnetization of fluid flowing through a given section of constricted pipe.

FIG. 15B is a graph of the normalized magnetization intensity of fluid flowing through various sections of a constricted pipe.

### DETAILED DESCRIPTION OF CERTAIN EMBODIMENTS

Various embodiments described herein provide magnetometers capable of detecting rapidly time-varying magnetic signals, such as radio frequency magnetic field oscillations. One useful application of such magnetometers is the detection of radio frequency magnetic fields generated in various nuclear resonance apparatuses (e.g., nuclear magnetic resonance (NMR) (including nuclear quadrupole resonance (NQR)) and magnetic resonance imaging (MRI). In one embodiment, an atomic magnetometer based on nonlinear magneto-optical rotation (NMOR) is used. An NMOR resonance occurs when optical pumping causes an atomic vapor to become dichroic (or birefringent), so that linearly polarized probe light experiences polarization rotation. In one embodiment, the atomic vapor in the magnetometer is optically pumped into an aligned quadrupole state. The magnetic field produced by such an aligned vapor is highly suppressed compared to that of an oriented vapor (one with a large dipole moment), thereby reducing the back reaction of the atomic magnetometer on the sample to be measured. In addition, optical pumping of the atomic vapor and optical detection of atomic polarization can be conducted using a single light beam when an aligned quadrupole state is used.

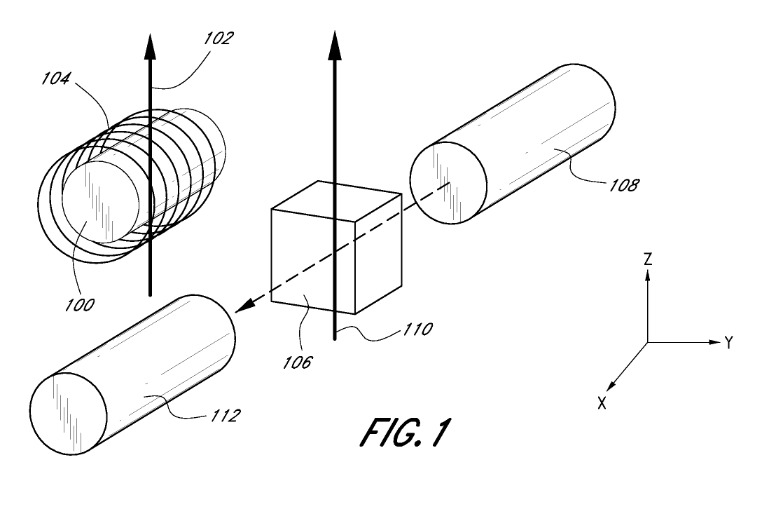

FIG. 1 is a system block diagram illustrating one apparatus for nuclear resonance detection using an atomic magnetometer. The nuclear sample 100 is exposed to a leading magnetic field 102. For reference purposes, the leading magnetic field 102 is considered to be aligned along the z axis. The leading magnetic field may be generated by any suitable means, including one or more inductor coils (e.g., a Helmholtz coil) or one or more permanent magnets. In some embodiments, a relatively low magnetic field strength is used (e.g., from about 1 mT to about 1 T). Such low field strengths eliminate the need for large and bulky magnets and are useful in several applications, including detection of scalar spin-spin (J) coupling. In nuclear quadrupole resonance measurements, the leading magnetic field may be eliminated. In other embodiments, larger magnetic field strengths are used, permitting the detection of chemical shift information.

The nuclear sample 100 is placed within an rf inductor coil 104 aligned transverse to the leading magnetic field 102. For reference purposes, the inductor coil 104 is considered to be aligned along the x axis. The inductor coil 104 may be used for sending pulsed rf magnetic signals to the nuclear sample along the x axis, rotating the nuclear polarization into the direction transverse to the leading field. The resulting free induction decay signal may then be detected by the magnetometer. Any number of rf pulse sequences known in the nuclear resonance arts may be used to generate the desired free induction signals, which are then detected by the magnetometer.

The magnetometer comprises a container 106 that contains an atomic vapor. The atomic vapor may be any suitable composition. In one embodiment, the atomic vapor comprises an alkali metal (e.g., rubidium and cesium). The container 106 is advantageously placed in close proximity to the nuclear sample 100 so as to maximize the field experienced by the atomic vapor due to the precessing nuclei. The atomic vapor is optically pumped into an aligned quadrupole state using a light source 108. The light source 108 may be any suitable source (e.g., a laser). In one embodiment, the optical pumping beam propagates along the x axis and is linearly polarized with the polarization direction aligned along the z axis (i.e., aligned along the leading magnetic field 102). The wavelength produced by the light source 108 may be selected to produce the desired optical pumping of the atomic vapor. For example, when rubidium vapor is used in the chamber 106, a diode laser tuned to the D1 line of rubidium may be used to excite the F=2→F′=1 transition.

The container 106 may be any container suitable for holding the atomic vapor and permitting the pump/probe light beam to pass through the walls of the container. For example, the container 106 may be glass or be equipped with glass windows. The excited state hyperfine structure may be resolved in order to use an aligned state. In one embodiment, this condition is satisfied by using a container with no buffer gas and interior walls coated with an anti-relaxation surface. In one embodiment, anti-relaxation properties are achieved by coating the interior of the container 106 with paraffin. Alternative coatings or container 106 materials may also be used to achieve anti-relaxation properties. By providing an anti-relaxation coating on the sides of the container 106, atoms can traverse the cell many times during the course of one relaxation period, effectively averaging the magnetic field over the cell, leaving the measurements insensitive to field gradients.

The atomic vapor in the container 106 may be exposed to a bias magnetic field 110 aligned along the z axis. The bias magnetic field 110 sets the Larmor precession frequency of the aligned ground state of the atomic vapor. In one embodiment, the bias magnetic field 110 of the magnetometer and the leading magnetic field 102 of the nuclear resonance apparatus are tuned such that the Larmor frequencies of the spins in the magnetometer and the spins of the nuclear sample are matched, resulting in maximum sensitivity. The bias magnetic field 110 may be generated by any suitable means, including one or more inductor coils (e.g., a Helmholtz coil) or one or more permanent magnets. In one embodiment, a single magnetic field generator is used to generate the both the leading magnetic field 104 and the bias magnetic field 110.

In one embodiment, the optical pumping beam is also used to probe the atomic vapor. The aligned atomic vapor exhibits linear dichroism and thus rotates the polarization vector of the linearly polarized light as it propagates through the vapor. As described in more detail below, the polarization oscillates in response to the free induction signal from the nuclear sample 100. This variation in polarization may be detected using a polarization detector 112. The polarization signal may then be analyzed (such as by using Fourier transformation) to determine component frequencies of the free induction signal and thus obtain the desired information regarding the nuclear sample 100. In one alternative embodiment, a probe light beam separate from the pump light beam is used to detect polarization rotation.

Unlike conventional inductive detection, the sensitivity of the magnetometer in the apparatus depicted in FIG. 1 does not depend on the strength of the leading magnetic field 102. Thus, significantly lower magnetic field strengths 102 may be used without a loss in sensitivity.

Although the apparatus depicted in FIG. 1 has been described to have certain alignments (e.g., leading and bias magnetic fields aligned along the z axis, rf coil and pump/probe light beam propagating along the x axis, and light polarization aligned along the z axis), it will be appreciated that other alignments are also operable. For example, having an angle between the leading and bias magnetic fields, an angle between the pump/probe beam and the bias magnetic field, and/or an angle between the light polarization vector and the bias magnetic field may still produce the desired results, albeit with less sensitivity.

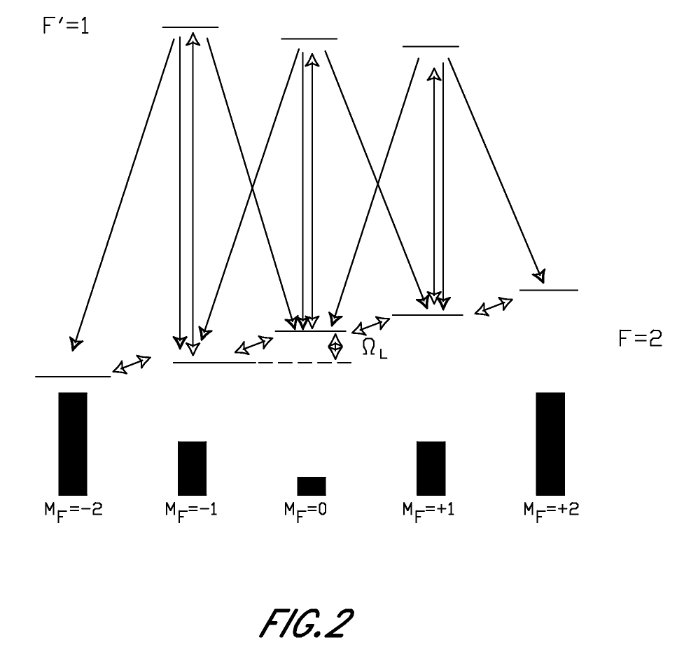

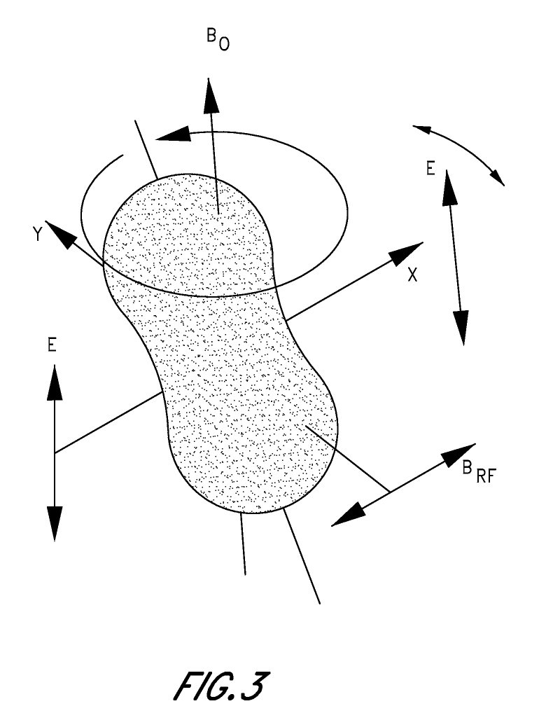

The principle of operation of the magnetometer is described in more detail with reference to the diagrams in FIGS. 2 and 3. FIG. 2 depicts the F=2 and F′=1 energy states for ⁸⁷Rb (I=3/2) in the presence of a z directed bias field B₀=B₀\hat{z}, corresponding to Larmor frequency Ω_{L}=gμ_{B}B₀/h, where μ_{B} is the Bohr magneton and g≈2/(2I+1) is the Landé factor. Linearly polarized light propagating in the x direction with polarization in the z direction, tuned to the D₁ (F=2→F′=1) transition, passes through the ⁸⁷Rb gas, optically pumping an aligned quadrupole state. With reference to FIG. 2, double headed vertical arrows indicate laser induced transitions between ground and excited states and dashed lines indicate transitions due to spontaneous decay. Relative ground-state populations are indicated by the solid black bars. As demonstrated by the black bars, a symmetrically distributed ground state is achieved such that the average magnetic field produced by the ⁸⁷Rb gas is suppressed compared to that from an oriented alkali vapor, thereby reducing any possible back-effect on a nuclear sample.

A convenient method for understanding the evolution and optical properties of the ground state is through the use of angular momentum probability surfaces, whose radius represents the probability of finding maximal projection of angular momentum along a given direction. FIG. 3 illustrates the polarization vector of the incident pump/probe beam on the left hand side, aligned with the z axis. The resulting aligned angular momentum is illustrated by the peanut shaped surface plot. The peanut distribution differentially absorbs light polarized parallel and perpendicular to its symmetry axis (linear dichroism), resulting in rotation of the polarization vector, as illustrated on the right hand side of the diagram.

In the presence of a small rf magnetic field oscillating in a direction transverse to the magnetic field with frequency close to Ω_{L} (e.g., such as produced by a nuclear resonance free induction signal), ground state transitions of |ΔM_{F}|=1 are possible. For purposes of illustration and without loss of generality, we assume the transverse field is oscillating along x, Bₓ=B₁ cos ωt, with ω˜Ω_{L}. The oscillating rf magnetic field can be resolved into components co- and counter-rotating with respect to the direction of Larmor precession, respectively, each of magnitude B₁/2. Transforming to the co-rotating frame, the counter-rotating component rapidly averages to zero and the magnetic field in the co-rotating frame is given by:

$${B}^{′} = \frac{h ( {Ω}_{L} - ω )}{g {μ}_{B}} \hat{z} + \frac{{B}_{1}}{2} \hat{x} \qquad ( 1 )$$

In steady state, an equilibrium is reached between optical pumping of alignment along the z axis, precession around B′, and relaxation, resulting in an aligned quadrupole state tilted away from the z axis. When Ω_{L}=Ω, the z component in equation (1) vanishes, resulting in the maximum angle between the aligned state and the z axis. When the system is transformed back into the lab frame, the tilted alignment precesses about the z axis as depicted in FIG. 3. The tilted alignment generates optical rotation through linear dichroism, maximal when the alignment is in the yz plane and none when it is in the xz plane, resulting in polarization rotation of the light beam that is modulated at a frequency Ω. For sufficiently small values of B₁ such that gμ_{B}B₁ is much less than the ground state relaxation rate, the amplitude of the polarization rotation modulation is linear in B₁. Thus, the polarization modulation signal may be processed to directly obtain the component frequencies (in the above example the single frequency Ω) present in the transverse free induction signal.

The description becomes slightly more complicated for higher light power and for light frequency detuned from optical resonance. Under these conditions, ac Stark shifts lead to differential shifts of the ground-state energy levels. In conjunction with precession in the rf magnetic field, this results in alignment-to-orientation conversion (AOC) in the rotating frame and a splitting of the rf NMOR resonance. Doppler broadening can also lead to AOC effects, even for resonant light. An additional high-light-power effect is the generation of the hexadecapole rank 4 polarization moment. It was found that optimal sensitivity is achieved when the saturation parameter is close to unity, but density-matrix calculations indicate that the hexadecapole contribution to the ground-state polarization is small compared to that of the quadrupole contribution for these conditions.

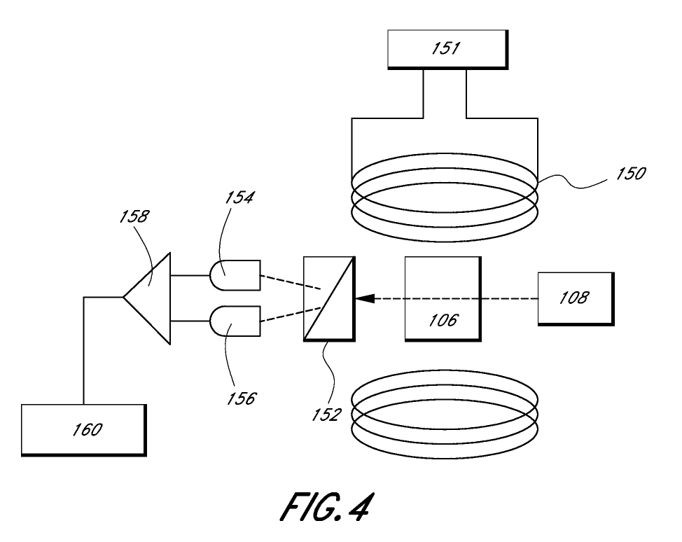

FIG. 4 is a system block diagram illustrating one embodiment of a magnetometer operating according to the above description. A container 106 is provided comprising an alkali metal vapor as described above. The alkali vapor may be heated to maintain a vapor state. In various embodiments, the vapor is heated to from about 30° C. to about 100° C., from about 40° C. to about 80° C., or from about 45° C. to about 60° C. A bias magnetic field may be generated and controlled by a Helmholtz coil 150. The Helmholtz coil may be driven by a current source 151. A laser source 108 is used to provide linearly polarized light to optically pump and probe the alkali vapor. Any suitable laser may be used. In one embodiment, the laser source 108 is a vertical-cavity surface-emitting diode laser. In another embodiment, the laser source 108 is a distributed feedback laser frequency-stabilized by a dichroic atomic vapor laser lock (DAVLL). Optimal light power depends on factors such as the number of atoms in the container 106 and the relaxation rate, but is typically somewhere from about 10 to about 200 μW. In various embodiments, the light power is from about 10 μW to about 200 μW, from about 20 μW to about 150 μW, or from about 50 μW to about 100 μW. After passing through the container 106, the polarization angle of the linearly polarized light beam may be detected by passing it through a Rochon polarizer 152 that splits the polarization components of the beam. The amplitude of each component is then detected by photodiodes 154 and 156. The difference photocurrent can then be amplified with a low-noise transimpedance amplifier 158 and the resulting signal transmitted to a signal processing module 160. In one alternative embodiment, the polarization rotation detector includes a polarizer nearly orthogonal to the incident beam polarization followed by a large-area avalanche photodiode module. Any other polarization detector known in the art may be used to detect the polarization angle of the linearly polarized light beam.

The signal processing module 160 may use any number of signal processing techniques for analyzing the polarization rotation (and hence magnetic field) signal. In cases where the signal includes a mix of frequencies, Fourier transformation may be used. In cases where only two frequencies are mixed (e.g., in scalar spin-spin (J) coupling experiments where only two spins are involved), the resulting beat signal may be analyzed to determine the component frequencies. In still other embodiments, a single frequency is present and may be analyzed using a lock-in amplifier or frequency counter, or analyzed directly in the time domain. Appropriate processors and other electronics may be incorporated within the signal processing module 160 for controlling the magnetometer and calculating, displaying, and/or storing the results.

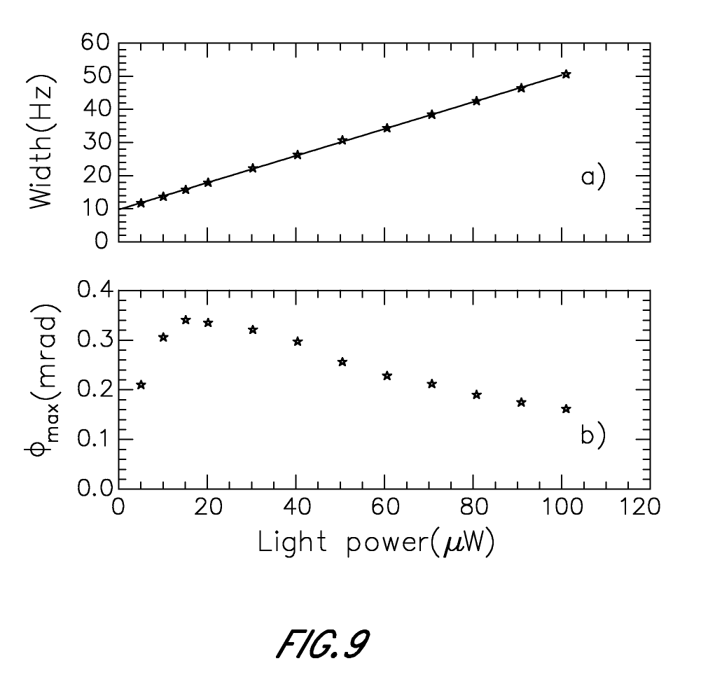

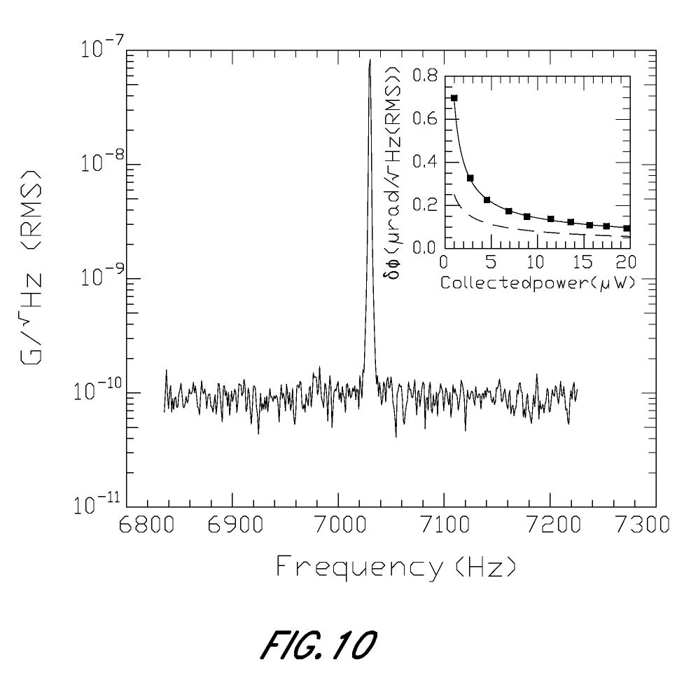

As described above, some embodiments include use of the above-described magnetometer for the detection of free induction signals generated by nuclear resonance apparatuses. However, other embodiments include use of the above-described magnetometer for the detection of any rapidly oscillating magnetic field, such as time-varying magnetic fields generated by geophysical phenomenon or other basic physics phenomenon. The magnetometer is sensitive to fields oscillating at frequencies within some bandwidth of the alkali Larmor precession frequency, which can be tuned to any desired value by adjusting the value of the bias field 110. The bandwidth depends on the relaxation rate of the alkali alignment and the light power. In the demonstration depicted in FIGS. 9 and 10 and described below, the bandwidth is about 100 Hz (twice the width in FIG. 9) for a light power of 100 μW, where sensitivity of 100 pG/√Hz was experimentally demonstrated. Bandwidths of up to 500 Hz may reasonably be expected for higher density vapors and light powers.

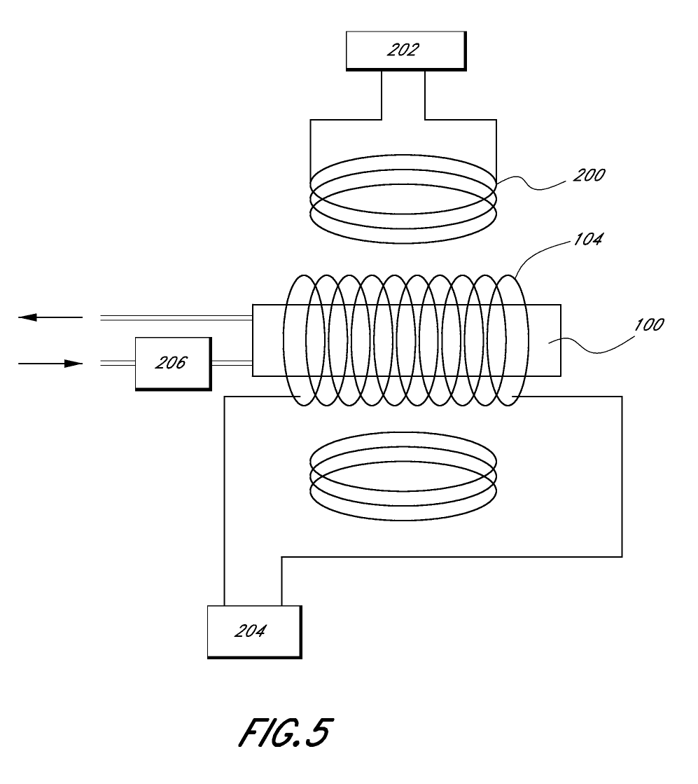

FIG. 5 is a system block diagram illustrating one embodiment of a nuclear resonance apparatus for generating a free induction signal that may be detected by the magnetometers described above. A nuclear sample 100 is positioned within two orthogonal coils. A first coil (e.g., a Helmholtz coil 200) is used to generate a leading magnetic field through the nuclear sample 100. The Helmholtz coil may be driven by a current source 202. A second rf coil 104 is provided for generating transverse rf signals to the nuclear sample 100. The rf coil 104 may be driven by an rf generator 204.

Traditional magnetic resonance techniques (e.g., pulse sequences) may be used for generating a free induction decay signal that may then be detected by the magnetometers described above. In one embodiment, the nuclear sample 100 is a solid sample that may be probed using nuclear quadrupole resonance techniques (e.g., by probing resonances in ¹⁴N, Deuterium, or other quadrupolar nuclei). In such an application, the leading magnetic field coil 200 is not required. Populations of the Zeeman sublevels of the ¹⁴N nuclei are determined by thermal polarization due to interaction of the nuclear quadrupole moment with electric field gradients native to the crystalline environment, resulting in alignment of the ¹⁴N nuclei. Application of RF pulses converts the alignment to orientation, which subsequently undergoes evolution in the native electric field gradient. This produces rapidly oscillating magnetic fields, at frequencies determined by the strength of the electric field gradient. These rapidly oscillating magnetic fields can then be detected by the atomic magnetometer described above. One application of such a system is explosives detection. For example, luggage to be probed for explosives may be passed into position within the coil 104 for application of RF pulses, with the atomic magnetometer located as close to the sample as possible.

In another embodiment, fluid nuclear samples are probed, such as in nuclear magnetic resonance or magnetic resonance imaging. In one embodiment, the fluid samples are also prepolarized to enhance sensitivity, such as by thermalization in a pulsed leading field, prepolarization in a separate magnetic field (e.g., using a strong electromagnet or permanent magnet), or hyperpolarization via spin-exchange with an optically pumped gas (e.g., xenon). In one optional embodiment depicted in FIG. 5, the fluid to be probed may be passed through a prepolarizing module 206 (e.g., a separate magnet) prior to flowing through a chamber within the nuclear resonance coils.

In magnetic resonance imaging applications, appropriate coils/magnets may be provided surrounding the nuclear sample 100 (e.g., a human body or portion thereof) for generating magnetic field gradients necessary for image formation.

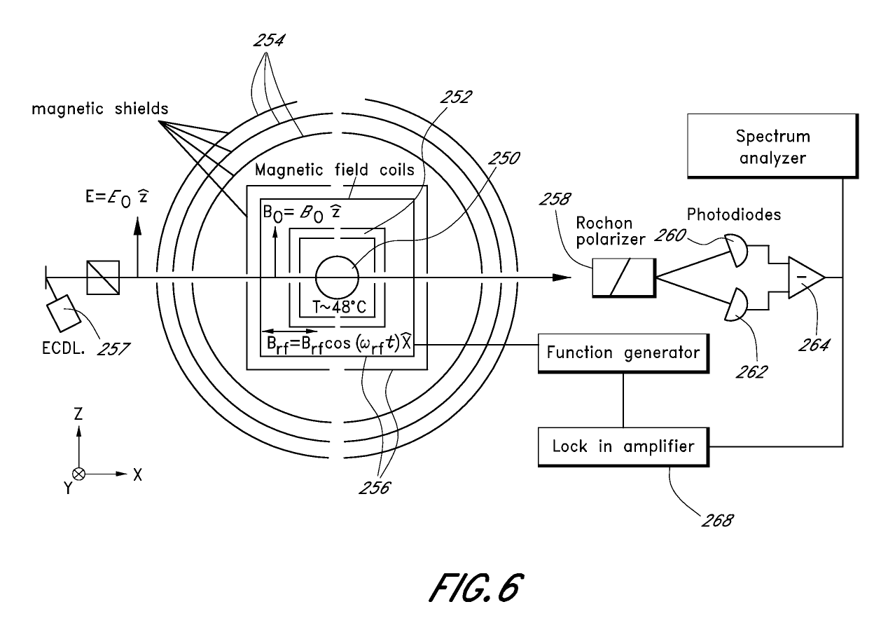

A magnetometer operating as described above and capable of detecting rf magnetic fields was constructed and tested. A schematic of the experimental setup is shown in FIG. 6. The measurements were performed with an evacuated, paraffin-coated spherical cell 250, 3.5-cm in diameter containing isotopically enriched ⁸⁷Rb (nuclear spin I=3/2). The paraffin coating enabled atomic ground-state polarization to survive several thousand wall collisions. The cell was placed inside a double-wall oven 252, temperature-controlled by flowing warm air through the space between the walls so that the optical path was unperturbed. A set of four nested μ-metal layers 254 provided a magnetically shielded environment, with a shielding factor of approximately 10⁶. A set of square, solenoidal coils 256 were set inside the innermost shield (cubic in profile). The coils were arranged so that each generates a magnetic field normal to a different set of parallel faces of the inner shield, yielding control of all three components of the magnetic field. The combination of currents applied to the coils and the image currents in the magnetic shields created “infinitely” long solenoids in three different directions. The atoms traverse the cell many times during the course of one relaxation period, effectively averaging the magnetic field over the cell, leaving the measurements insensitive to field gradients. A static magnetic field B₀ was applied in the z direction and a small oscillating magnetic field B₁ cos Ωt was applied in the x direction (B₁=110 nG and B₀=10 mG). Eddy currents in the inner shield layer could alter the amplitude of the oscillating field as a function of Ω. Thus, the amplitude of the oscillating magnetic field was checked via a pick-up coil to verify that it varied by less than 10% from 100 Hz to 10 kHz at the location of the cell.

A collimated beam with diameter of 3 mm from an external-cavity diode laser 257 was propagated in the x direction with polarization vector in the z direction. Unless otherwise stated, these measurements were performed with the light tuned to the center of the F=2→F′=1 transition (henceforth referred to as optical resonance). On account of distortion of the light beam by the cell, only 20% of the light that passed through the cell was collected (as determined by tuning the laser far away from optical resonance). The polarization of this light was monitored using a balanced polarimeter incorporating a Rochon polarizer 258, two photodiodes 260 and 262, and a differential amplifier 264, and detected synchronously using a lock-in amplifier 268. Number density was determined by monitoring the transmission of a low-power beam through the cell as a function of laser frequency. The cell temperature was 48° C., and the measured number density was n=7×10¹⁰ (within 20% of that expected from the saturated vapor pressure at this temperature), corresponding to approximately one absorption length for resonant light.

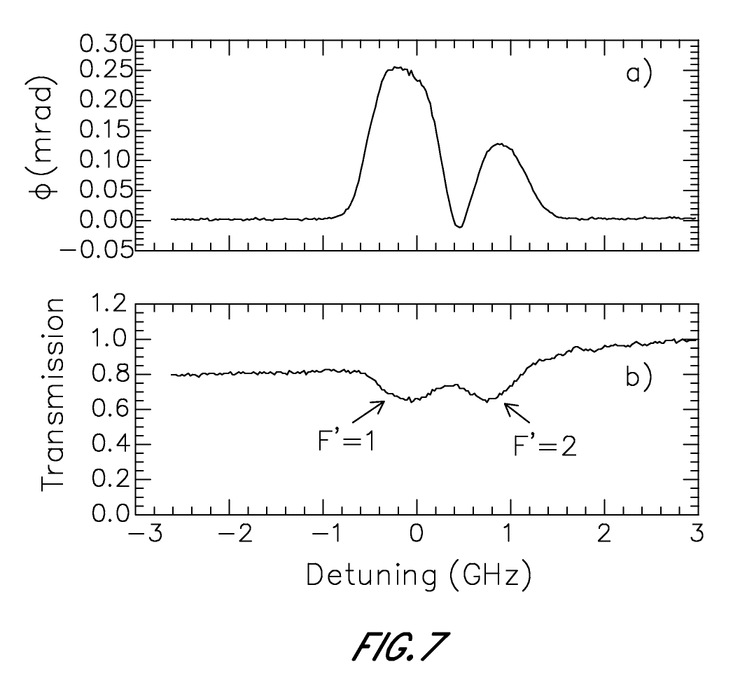

FIG. 7, panel A is a graph of the in-phase component of the synchronously detected optical rotation as a function of light frequency for ω=Ω_{L}. For these data, the light power was 60 μW (850 μW/cm₂). FIG. 7, panel B is a graph of the partially saturated transmission curve under the same experimental conditions. The background slope of the transmission curve is due to varying laser intensity as the diode laser feedback grating is swept. The largest optical rotation occurs for light tuned near the center of the F=2→F′=1 transition. At the light powers for which optimal sensitivity on the F=2 component was obtained, optical rotation on the F=1 component was at least an order of magnitude smaller than that produced by the F=2 component.

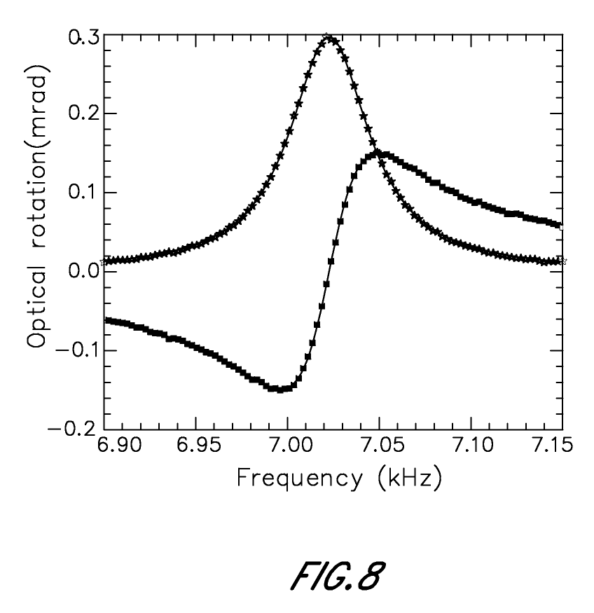

FIG. 8 is a graph depicting the synchronously detected in-phase (stars) and quadrature (squares) components of optical rotation for light tuned to optical resonance and incident light power of 40 μW. Overlaying these components are a fit to a single absorptive (or dispersive) Lorentzian. The peak in the in-phase component corresponds to the Larmor frequency.

FIG. 9, panel A is a graph the half width at half maximum (Δυ) of the in-phase component of the rf NMOR resonance as a function of light power (the distance from the center of the resonance to the extrema of the quadrature signal is also given by Δυ (see FIG. 8)). Overlaying the data is a linear fit with zero-power width Δυ₀=9.7 Hz. The intrinsic polarization relaxation rate is related to Δυ. Ground state relaxation in paraffin coated cells is typically dominated by electron randomization during collisions with the cell walls and through alkali-alkali spin exchange collisions.

FIG. 9, panel B is a graph of the amplitude φₘₐₓ of the rf NMOR resonance shown in FIG. 8 (defined as the maximum of the in-phase component) as a function of light power. The amplitude increased as a function of light power for low light power, until reaching a maximum at around 15 μW. Beyond saturation, the amplitude decreased due to light broadening.

FIG. 10 is a graph depicting the noise spectrum of the magnetometer measured by an SRS770 spectrum analyzer at the output of the balanced polarimeter. The large peak is an applied filed of 83 nG (rms) to calibrate the magnetometer. Baseline noise is about 100 pG/√Hz (rms). In order to assess the performance of the polarimeter, shown inset in FIG. 10 is the measured noise floor (squares) as a function of light power incident on the polarimeter. The dashed line represents photon shot noise δφₚₕ=1/(2\sqrt{Φₚₕ})=0.35 μrad √μW/√Hz (rms) where Φₚₕ is the number of photons per second incident on the polarimeter. For light power greater than about 10 μW, the measured noise was within 20% of the photon shot-noise limit. Polarimeter noise can be parameterized by

δφ=\sqrt{ζₚₕ²/P+ζₐₘₚ²/P2} (2)

Here, P is the power incident on the polarimeter and ζₚₕ and ζₐₘₚ parameterize photon shot noise and the differential amplifier noise, respectively. The solid line overlaying the data is a fit based on Eq. 2, resulting in ζₐₘₚ=0.55 μrad μW/√Hz (rms) and ζₚₕ=0.41 μrad √μW/√Hz (rms), close to the theoretically predicted value. Hence, amplifier noise was the dominant contribution for incident light power less than about 2 μW and photon shot noise dominates for higher light power.

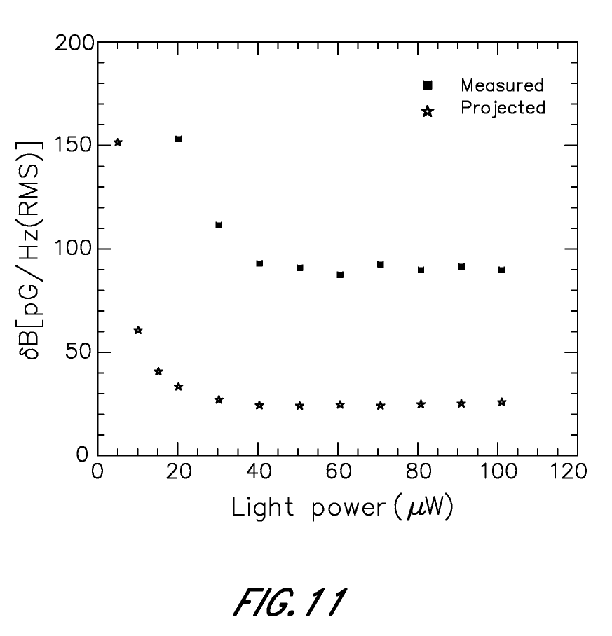

FIG. 11 is a graph of the projected sensitivity of the magnetometer (stars) (δBₚᵣₒⱼ=δφ(B₁/φₘₐₓ)) based on the amplitude of the rf NMOR resonance shown in FIG. 9, panel B and detection of the light at the photon shot noise limit. In estimating the photon shot-noise, the light power was measured after the beam passed through the shields and multiplied by a factor of 5 to account for absorption of the light by the atomic vapor as well as loss of light due to distortion of the light beam by the cell. Optimum projected sensitivity of about 25 pG/\sqrt{Hz} (rms) occurs at about 40-50 μW input light power and remains roughly constant out to 100 μW. For comparison, the measured noise floor (squares) determined from spectra like that shown in FIG. 10 as a function of light power is also plotted. One reason for coming short of the projected sensitivity limit is the factor of 5 loss in light power which results in a factor of √5 loss in sensitivity.

The bandwidth of the magnetometer was also determined (defined here as full width at half maximum of the in-phase component of the rf NMOR resonance). Referring to FIG. 8, it can be seen that the bandwidth is about 50 Hz at 40 μW. By increasing light power to 100 μW, it is anticipated that the bandwidth can be doubled with little loss in projected sensitivity.

Another application of the magnetometer described above includes the remote monitoring of the flow of fluidic analytes. In one such embodiment, the fluidic analytes are labeled via enhanced nuclear magnetization through exposure of the analytes to a magnetic field. The enhanced magnetization can then be detected using the atomic magnetometer downstream of the encoding region. The region of analyte flow of interest can be selectively exposed to the magnetic field, thereby encoding only the region of interest for detection by the magnetometer. Because the magnetization can be directly detected by the magnetometer, no encoding pulses are required.

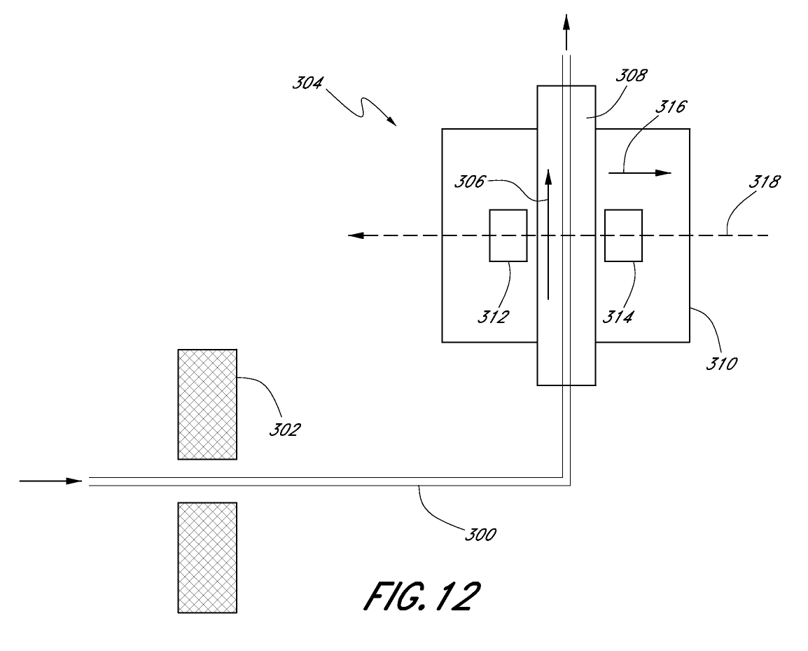

A system block diagram of one embodiment of fluidic analyte detection is depicted in FIG. 12. The fluid of interest flows through a tube 300 that passes through a polarizing magnet 302 and then through a magnetometer system 304. The polarizing magnet 302 enhances the nuclear magnetization of the fluid, which can then be detected by the magnetometer system 304. In some embodiments, the magnet 302, which may be a permanent magnet or electromagnet, may be moved along the tube 300 to encode different regions of the fluid flow. In other embodiments, selective energizing of a plurality of electromagnetic coils along the tube 300 may be used to select the region of encoding.

Once inside the magnetometer system 304, the fluid can be exposed to a leading magnetic field 306 generated by a solenoid 308 the pierces the magnetic shielding 310 of the magnetometer system 304. The polarized fluid sample then changes the magnetic field strength within alkali cells 312 and 314 within the magnetometer system 304, allowing detection of the fluid magnetization. In the depicted embodiment, two alkali cells 312 and 314 are utilized, effectively creating a gradiometer, which allows the cancelation of the applied bias filed and the elimination of common-mode noise. As described above, the alkali cells 312 and 314 are exposed to a bias magnetic field 316 and linearly polarized light 318.

In one embodiment, in order to distinguish the signal from slow drifts, the polarizing magnetic field is modulated with a given frequency. The modulation may be generated through the use of electromagnets or physically moving permanent magnets towards and away from the fluid tube 300. The raw magnetization modulation measured by the magnetometer system 304 may be Fourier transformed to isolate the signal detected at the modulation frequency.

The measured magnetization of the fluid sample depends on its residence time in the polarization magnetic field and its travel time from the polarization region to the detection region. A simple model of magnetization provides:

$$M = {M}_{0} ( 1 - exp ( \frac{- v}{{R}_{f} {T}_{1}} ) ) exp ( \frac{- V}{{R}_{f} {T}_{1}} ) \qquad ( 3 )$$

The first exponential term in Eq. 3 describes the magnetization that the sample gains during the encoding/polarization phase. The second exponential term accounts for the relaxation of the magnetization during the flow from the encoding region to the detection region. M₀ is the maximum magnetization that can be gained by thermal polarization from the magnetic field of the magnets, ν is the volume of the section being magnetized, T₁ is the relaxation time of the nuclear magnetization (1.6 s for water with concentrations of oxygen corresponding to equilibrium with the atmosphere), V is the total downstream volume between the encoding/polarization volume and the detector, and R_{f} is the volume flow rate. Once the relationship between encoding region volume and magnetization is calibrated, the volume of fluid within various regions of the fluid tube 300 can be determined from the magnetization given a known flow rate. Alternatively, if the encoding volume is known, the flow rate can be determined from magnetization.

The above-described technique may be used to remotely characterize fluid flow in wide variety of applications including fluid flow through metal tubing/piping. In one embodiment, the technique is used to detect blood flow at the intersection of blood vessels. A magnet can be appropriately positioned with respect to an artery or vein. A small-sized magnetometer can be placed on the patient, downstream from the polarization/encoding site. This arrangement detects a volume separate from the encoding volume and allows characterization of mixing in vessel junctions or spin relaxation occurring within the vessels. In combination with appropriate contrast agents, this may allow detection of abnormal tissues.

A system such as depicted in FIG. 12 was constructed to test the measurement of fluid flow using an atomic magnetometer. Two anti-relaxation-coated glass cells filled with rubidium-87 (Rb) were positioned adjacent to the detection volume. Linearly polarized light tuned to the rubidium D1 line was used to produce alignment of the ground state via optical pumping. The polarization of the laser beams after they passed through the Rb vapor cells was monitored via balanced polarimeters. The fluid sample within the detection region was subjected to a leading field of 0.5 G provided by a solenoid that pierces the magnetic shield.

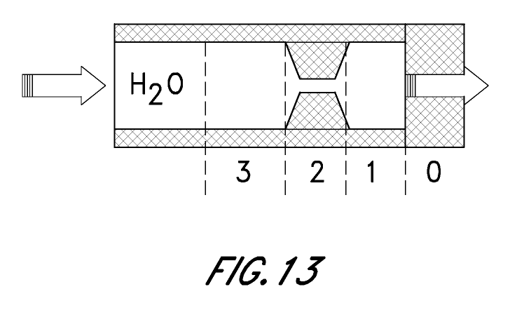

Backed by high-pressure nitrogen (5.2 bar), water flowed at 30 ml/min through a structured tube. FIG. 13 depicts a cross section of the structured tube. The tube has four sections; section 0 is the outlet of the pipe, which has negligible volume, sections 1 and 3 are non-constricted (inner diameters of 4.9 mm) portions of pipe while section 2 is constricted (inner diameter 1.6 mm). Sections 1 through 3 are 6.4 mm long. The water sample was magnetized by six 6.4×6.4×6.4 mm³ neodymium-iron-boron magnets arranged with three on either side of a section. This created a field of 3 kG between the magnets, which falls to 100 G at a distance, along the direction of flow, of 3 mm from the edge of the magnets. To distinguish the signal from slow drifts, the magnets were moved 2 cm away from the tube with a given frequency. To measure the internal structure of the tube, the magnets were placed along each section.

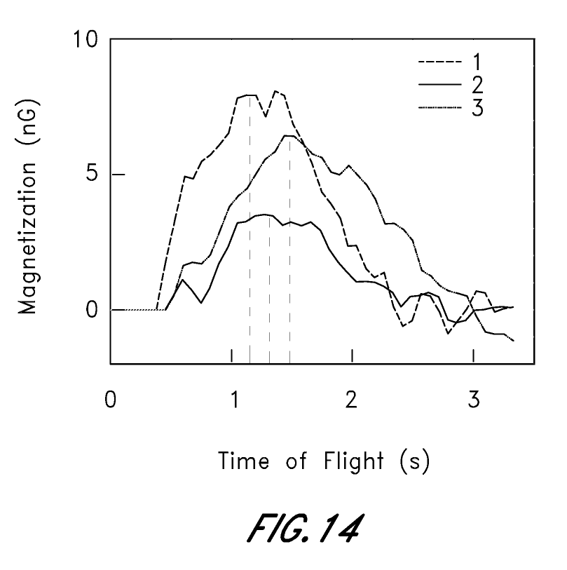

Temporal signal averages for sections 1, 2, and 3 were obtained. FIG. 14 is graph depicting the resulting temporal signal averaged magnetization measured as a function of time-of-flight when the polarizing magnet was positioned at each of three sections. These are the signal from each modulation cycle averaged together; a modulation cycle of 1.5 polarized and 1.5 seconds unpolarized was used. The characteristics of these signals are dictated by the distance of the encoding region from the detector and the volume of the encoding region. The peak from section 3 occurred ˜0.3 s later than the peak from section 1, roughly corresponding to the time it takes to traverse that distance. The magnitude of the maximum signal of the former was consequently lower than that of the latter because of the relaxation and flow velocity dispersion that occurs in the ˜0.3 s. Section 2 showed the lowest signal of the three, a result of its small volume. A smaller volume increases the linear flow rate decreasing the residence time of the water in the constriction and consequently the magnetization.

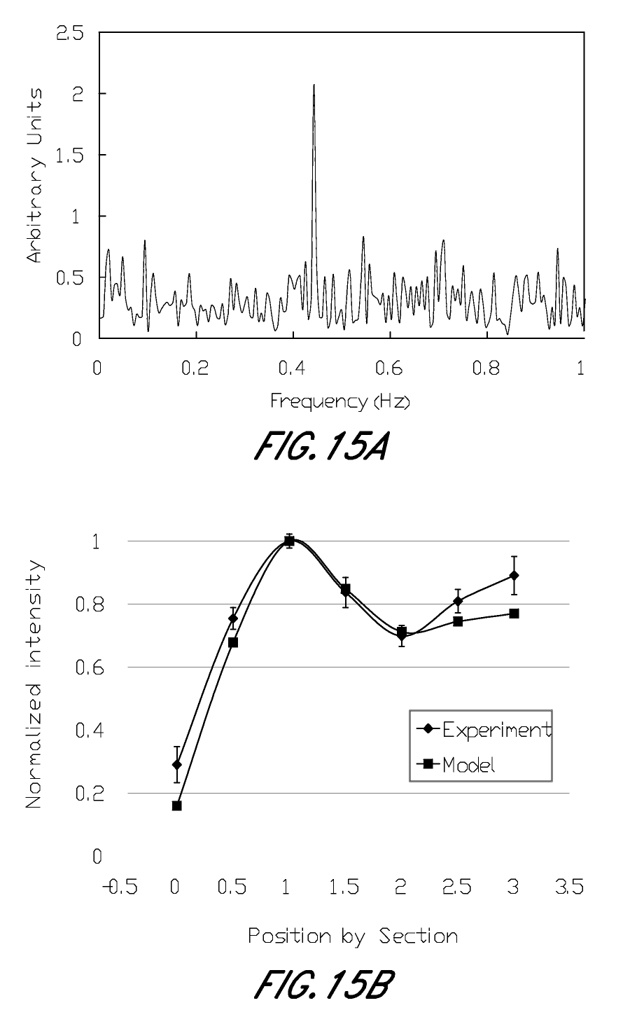

To gain quantitative information, the raw modulation cycle signal from each section was Fourier transformed. FIG. 15A depicts the Fourier transform of the raw data corresponding to a time series of 50 modulation cycles for section 1. The magnets were modulated at 0.50 Hz: 1.0 second for polarization, corresponding to approximately 0.5 ml, and 1.0 second to separate the polarized-water volumes by unpolarized water. The signal approximates a sine wave as the water in the encoding region gains magnetization, but is not allowed to return to equilibrium because of the fast modulation frequency. The amplitude at 0.50 Hz represents the magnitude of signal from the modulation of the magnets. A plot of the signal at 0.50 Hz as a function of the position of the magnet is shown in FIG. 15B. The positions in FIG. 15B are defined by which sections were covered by the polarizing magnets. The value at section 1 is the measurement taken when the magnet completely covered section 1, which the value at section 1.5 is the value measured when the magnets covered half of section 1 and half of section 2. The proton magnetization in the water depends on its residence time in the magnetic field and its travel time from the polarization region to the detection region. Overlaying the experimental data in FIG. 15B are the results obtained based on the model of Equation (3).

The signals depicted in FIG. 15B, were used to calculate the volume of each section if the volume of one section is known using the equation,

$$\frac{{S}_{1}}{{V}_{1}} = \frac{{S}_{2}}{{V}_{2}} exp \frac{{V}_{1}}{{R}_{f} {T}_{1}} \qquad ( 4 )$$

Here S₁ and S₂ are the signals from sections 1 and 2 respectively, and V₁ and V₂ are the volumes for section 1 and 2, respectively. Assuming that the volume in section 1 is known, the volume of section 2 was determined to be 0.090 cm³, which is comparable to its measured volume of 0.096 cm³. The model and experiment for section 3 show a deviation of roughly 14%, as can be seen in FIG. 15B. The signal rises as expected but the signal is higher than predicted by the model. A more sophisticated model including factors such as flow dispersion may account for the details of the observed signals.

The competition between polarization and relaxation allows a range of acceptable flow rates and measurement volumes. For a given flow rate, a large-volume tube will lead to increased relaxation before it has reached the detector. A lower bound is dictated by the residence time in the encoding region. As volumes contract, the residence time decreases meaning less polarization is gained by the sample. Decreasing the flow rate will increase the polarization time, but also the travel time. The characteristics of the system being examined would dictate the flow rate, as to balance these factors. If one moves the detection region to just after the encoding region sections with a much larger volume can be used.

Although the invention has been described with reference to embodiments and examples, it should be understood that numerous and various modifications can be made without departing from the spirit of the invention. Accordingly, the invention is limited only by the following claims.

What is claimed is:

1. A magnetometer, comprising:
a container comprising atomic vapor;
a magnetic field generator configured to apply a substantially static magnetic field to the atomic vapor; and
a linearly polarized light source configured to optically pump the atomic vapor into a substantially aligned state.

2. The magnetometer of claim 1, comprising a light polarization detector configured to detect a polarization angle of the linearly polarized light after it passes through the atomic vapor.

3. The magnetometer of claim 2, comprising a processor configured to determine component frequencies in variation of the polarization angle.

4. The magnetometer of claim 1, comprising:
a second linearly polarized light source configured to transmit light through the atomic vapor; and
a light polarization detector configured to detect a polarization angle of light from the second linearly polarized light after it passes through the atomic vapor.

5. The magnetometer of claim 4, comprising a processor configured to determine component frequencies in variation of the polarization angle.

6. The magnetometer of claim 1, wherein the container comprises an interior paraffin coating.

7. The magnetometer of claim 1, wherein the atomic vapor comprises an alkali metal.

8. The magnetometer of claim 1, wherein the atomic vapor comprises rubidium.

9. The magnetometer of claim 1, wherein the magnetic field generator comprises one or more inductor coils.

10. The magnetometer of claim 1, wherein the light source is configured to irradiate the atomic vapor with light linearly polarized along the magnetic field.

11. A method of detecting time-varying magnetic fields, the method comprising:
exposing an atomic vapor to a substantially static magnetic field;
optically pumping the atomic vapor into a substantially aligned state;
exposing the atomic vapor to a time-varying magnetic field;
transmitting linearly polarized light through the atomic vapor; and
detecting modulation of the polarization angle of the linearly polarized light.

12. The method of claim 11, wherein the substantially static magnetic field is generated using one more inductor coils.

13. The method of claim 11, wherein the optical pumping comprises irradiating the atomic vapor with linearly polarized light.

14. The method of claim 13, wherein the optical pumping light is the same as said linearly polarized light transmitted through the atomic vapor.

15. The method of claim 13, wherein the optical pumping comprises irradiating the atomic vapor with light linearly polarized along the static magnetic field.

16. The method of claim 11, comprising determining component frequencies in the detected modulation.

17. A nuclear resonance detector, comprising:
a first magnetic field generator configured to apply a magnetic field to a sample;
an inductor coil configured to apply a time-varying magnetic field to the sample at an angle relative to the magnetic field applied by the first magnetic field generator;
a container comprising atomic vapor; and
a linearly polarized light source configured to optically pump the atomic vapor into a substantially aligned state.

18. The detector of claim 17, comprising a light polarization detector configured to detect a polarization angle of the linearly polarized light after it passes through the atomic vapor.

19. The detector of claim 18, comprising a processor configured to determine component frequencies in variation of the polarization angle, wherein the component frequencies correspond to nuclear resonance frequencies in the sample.

20. The detector of claim 17, comprising:
a second linearly polarized light source configured to transmit light through the atomic vapor; and
a light polarization detector configured to detect a polarization angle of light from the second linearly polarized light after it passes through the atomic vapor.

21. The detector of claim 20, comprising a processor configured to determine component frequencies in variation of the polarization angle, wherein the component frequencies correspond to nuclear resonance frequencies in the sample.

22. The detector of claim 17, comprising a second magnetic field generator configured to apply a magnetic field to the atomic vapor.

23. The detector of claim 22, wherein the second magnetic field generator comprises at least one inductor coil.

24. The detector of claim 22, wherein the second magnetic field generator comprises at least one permanent magnet.

25. The detector of claim 22, wherein the light source is configured to irradiate the atomic vapor with light linearly polarized along the magnetic field generated by the second magnetic field generator.

26. The detector of claim 17, wherein the first magnetic field generator comprises at least one inductor coil.

27. The detector of claim 17, wherein the first magnetic field generator comprises at least one permanent magnet.

28. The detector of claim 17, wherein the container comprises an interior paraffin coating.

29. The detector of claim 17, wherein the atomic vapor comprises an alkali metal.

30. The detector of claim 17, wherein the atomic vapor comprises rubidium.

31. The detector of claim 17, wherein the angle is substantially perpendicular.

32. A method of nuclear resonance detection, comprising:
generating a magnetic free precession signal from a sample;
exposing an atomic vapor to the free precession signal;
optically pumping the atomic vapor into a substantially aligned state;
transmitting linearly polarized light through the atomic vapor; and
detecting modulation of the polarization angle of the linearly polarized light.

33. The method of claim 32, wherein the optical pumping comprises irradiating the atomic vapor with linearly polarized light.

34. The method of claim 33, wherein the optical pumping light is the same as said linearly polarized light transmitted through the atomic vapor.

35. The method of claim 32, comprising determining component frequencies in the detected modulation.

36. The method of claim 35, wherein said component frequencies correspond to component frequencies of the free precession signal.

37. The method of claim 32, wherein generating the magnetic free precession signal comprises exposing the sample to a substantially static magnetic field along a first direction, and exposing the sample to a periodic magnetic field along a second direction at an angle to the first direction.

38. The method of claim 37, wherein the angle is substantially perpendicular.

39. A method of detecting fluid, comprising:
exposing a flowing fluid to a magnetic field to enhance nuclear magnetization within the fluid; and
detecting the enhanced nuclear magnetization with a magnetometer downstream of where the fluid is exposed to the magnetic field.

40. The method of claim 39, wherein exposing the fluid to a magnetic field comprises positioning a magnet in proximity to the fluid.

41. The method of claim 40, wherein the magnet is a permanent magnet.

42. The method of claim 40, wherein the magnet is an electromagnet.

43. The method of claim 39, wherein the magnetic field is modulated.

44. The method of claim 43, wherein modulating the magnetic field comprises physically moving a magnet.

45. The method of claim 43, comprising Fourier transforming the detected nuclear magnetization.

46. The method of claim 45, comprising selecting a magnetization signal corresponding to a frequency of the magnetic field modulation from the Fourier transformation.

47. The method of claim 39, comprising determining a volume of fluid from the detected nuclear magnetization.

48. The method of claim 39, comprising determining a fluid flow rate from the detected nuclear magnetization.

49. The method of claim 39, wherein the magnetometer is an atomic magnetometer.

50. The method of claim 49, wherein the atomic magnetometer comprises a container comprising atomic vapor and a linearly polarized light source configured to optically pump the atomic vapor into a substantially aligned state.

51. The method of claim 39, wherein the fluid is flowing through a metal tube or pipe.

52. The method of claim 39, wherein the fluid is blood flowing through a vein or artery.
